(19) United States
(12) Patent Application Publication
(10) Pub. No.: US 2025/0191893 A1
(43) Pub. Date: Jun. 12, 2025

(54) SPARK PLASMA SINTERED COMPONENT FOR CRYO-PLASMA PROCESSING

(71) Applicant: Lam Research Corporation, Fremont, CA (US)

(72) Inventors: Lin XU, Fremont, CA (US); Satish SRINIVASAN, Newark, CA (US); Harmeet SINGH, Fremont, CA (US); John DAUGHERTY, Fremont, CA (US); Pankaj HAZARIKA, Sherwood, OR (US)

(21) Appl. No.: 18/844,917

(22) PCT Filed: Mar. 21, 2023
(86) PCT No.: PCT/US2023/015810

§ 371 Date: Sep. 6, 2024

Related U.S. Application Data
(60) Provisional application No. 63/322,982, filed on Mar. 23, 2022.

(51) Int. Cl. H01J 37/32; C04B 35/565; C04B 35/64; H01L 21/67

(52) U.S. Cl. CPC H01J 37/32642; C04B 35/565; C04B 35/64; H01J 37/3244; H01J 37/32724; C04B 2235/3826; C04B 2235/612; C04B 2235/666; H01J 2237/002; H01J 2237/334; H01L 21/67069

(57) ABSTRACT

An apparatus for plasma processing a wafer at cryogenic temperatures is provided. A wafer support is adapted to support a wafer within a plasma processing chamber. A gas source provides gas to the plasma processing chamber. A cooling system provides cooling the wafer support. A component comprises a spark plasma sintered body comprising a sintering powder comprising at least one of a doped silicon carbide powder, wherein a dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B4C), WC, or TaC and wherein a dopant is at least one of B, W, molybdenum (Mo), Al, and Ta, or pure B4C, WC, TaC, W, or Mo.

### CROSS-REFERENCE TO RELATED APPLICATION

This application claims the benefit of priority of U.S. Application No. 63/322,982, filed Mar. 23, 2022, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to parts for use in a plasma processing chamber. More specifically, the disclosure relates to dielectric, plasma exposed parts in a plasma processing chamber.

In forming semiconductor devices, plasma processing chambers are used to process the substrates. Some plasma processing chambers have dielectric parts, such as liners, gas distribution plates, and edge rings.

For some of the dielectric parts for plasma processing chambers, silicon carbide (SIC) has been widely used due to the high etch resistance of SiC. The technique to produce a SiC edge ring is predominantly through a chemical vapor deposition (CVD) method where a thick SiC coating is grown onto a graphite mandrel. After the removal of the graphite mandrel, the CVD-produced SiC blank is then machined into an edge ring. With more aggressive plasma chemistries and more stringent demand in a part lifetime, CVD-produced pure SiC cannot meet lifetime requirements.

It has been found that for cryogenic plasma processing, such as cryogenic etching, the life of a component, such as an edge ring, would be four to five times lower than the lifetime of the component in noncryogenic plasma processing.

### SUMMARY

To achieve the foregoing and in accordance with the purpose of the present disclosure, an apparatus for plasma processing a wafer at cryogenic temperatures is provided. A wafer support is adapted to support a wafer within a plasma processing chamber. A gas source provides gas to the plasma processing chamber. A cooling system provides cooling the wafer support. A component comprises a spark plasma sintered body comprising a sintering powder comprising at least one of a doped silicon carbide powder, wherein a dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein a dopant is at least one of B, W, molybdenum (Mo), Al, and Ta, or pure B₄C, WC, TaC, W, or Mo.

In another manifestation, a component for use in a cryogenic plasma processing system is provided comprising a spark plasma sintered body comprising a sintering powder comprising at least one of a doped silicon carbide powder, wherein a dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein a dopant is at least one of B, W, molybdenum (Mo), Al, and Ta, or pure B₄C, WC, TaC, W, or Mo.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2A-FIG. 2D show an embodiment of a method for fabricating an edge ring component for use in a plasma processing chamber. FIG. 2A is a cross-sectional view of a sintering powder placed in a mold. FIG. 2B is a cross-sectional view of an edge ring formed after spark plasma sintering (SPS) the sintering powder. FIG. 2C is a side view of the edge ring removed from the mold. FIG. 2D is a side view of the edge ring after further processing to form an edge ring component for use in a plasma processing chamber.

FIG. 3A-FIG. 3F show an embodiment of a method for fabricating a gas distribution plate component for use in a plasma processing chamber. FIG. 3A is a cross-sectional view of a sintering powder placed in a mold. FIG. 3B is a cross-sectional view of a gas distribution plate formed after spark plasma sintering (SPS) the sintering powder. FIG. 3C is a plan view of the gas distribution plate removed from the mold. FIG. 3D is a side view of the gas distribution plate of FIG. 3C. FIG. 3E is a plan view of the gas distribution plate after further processing to form a gas distribution plate component for use in a plasma processing chamber. FIG. 3F is a side view of the gas distribution plate component of FIG. 3E.

FIG. 4 is a schematic view of a plasma processing chamber according to an embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

In plasma processing, various components of a plasma processing chamber may be eroded. The eroded component causes changes in the process, which may affect wafer to wafer uniformity. In addition, an eroded component may need to be replaced increasing down time of the plasma process, decreasing throughput, and increasing cost of ownership. Cryogenic plasma processing is plasma processing at a temperature of less than −20° C. It has been found that cryogenic plasma processing, such as cryogenic etching may cause components to erode four to five times faster than the components would for non-cryogenic plasma processing. In some applications, it has been found that plasma processing at cryogenic temperatures provides improved processes. Increased erosion from using such cryogenic temperature plasma processing would increase downtime, increase cost of ownership, degrade system performance, and lower throughput.

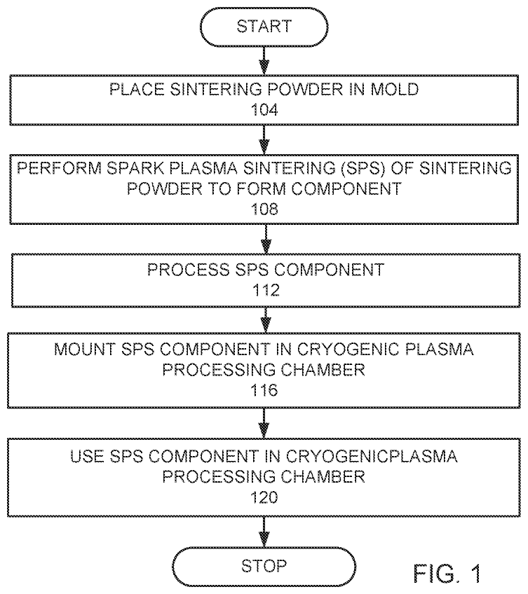

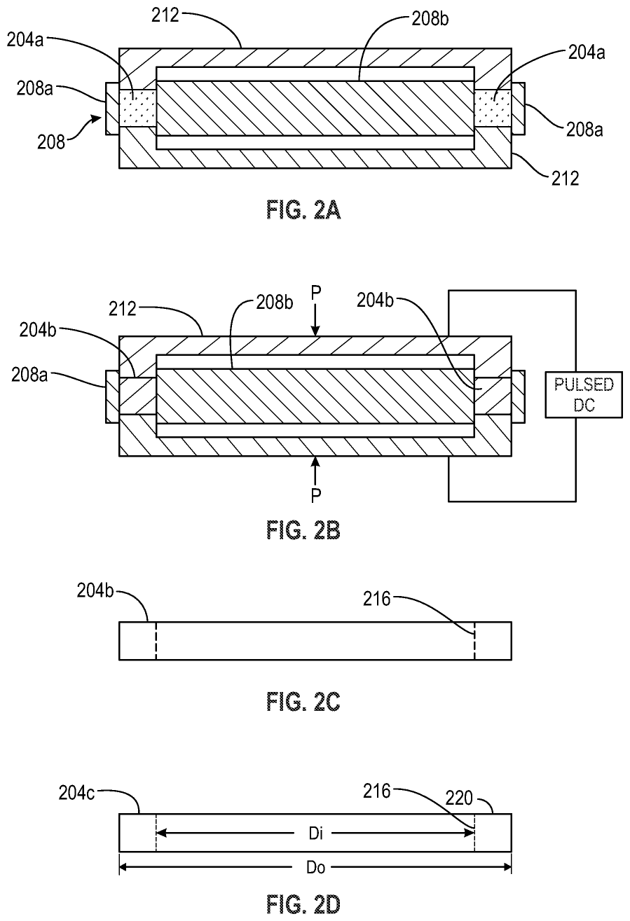

To facilitate understanding, FIG. 1 is a high level flow chart of an embodiment of a method of fabricating a component for a plasma processing chamber. A sintering powder is placed in a mold (step 104). In this embodiment, the sintering powder comprises at least one of a doped silicon carbide powder, wherein the dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein the dopant is at least one of B, W, molybdenum (Mo), Al, or Ta, or may be pure MoC, B₄C, WC, TaC, W, or Mo. In one embodiment, the atomic fraction of dopant to total powder is in the range of 0.01% to 30%. In other embodiments, the atomic fraction of dopant to total powder is in the range of 0.05% to 20%. In other embodiments, the atomic fraction of dopant to total powder is in the range of 0.1% to 10%. In other embodiments, the atomic fraction of dopant to total powder is in the range of 0.1% to 1%. In other embodiments, the atomic fraction of dopant to total powder is in the range of 1% to 5%. In other embodiments, the atomic fraction of dopant to total powder is in the range of 1% to 10%. In other embodiments, the atomic fraction of dopant to total powder is greater than 10%. FIG. 2A shows a cross-section view of sintering powder 204a placed in an annular recess or cavity of a mold 208 for fabricating a component of a plasma processing chamber. The mold 208 comprises an outer mold ring 208a and an inner mold 208b. In this example, the component is an edge ring for use in a plasma processing chamber. The mold 208 is configured for processing the sintering powder 204a according to a Spark Plasma Sintering (SPS) process, and in one embodiment includes a pair of conductive pads 212 that enclose upper and lower ends of the mold 208 cavity and act as pistons or punches to apply a compressive force P on the sintering powder 204a within the mold 208.

Referring back to FIG. 1, the sintering powder 204a is then subjected to Spark Plasma Sintering (SPS) to form sintering powder into a Spark Plasma Sintered part or component (step 108). In the exemplary embodiment illustrated in the cross-section view of FIG. 2B, the sintering powder 204a is then subjected to SPS to form the sintering powder into a Spark Plasma Sintered formed edge ring 204b.

As compared to conventional sintering processes, the SPS process (also referred to as pulsed electric current sintering (PECS), Field-Assisted Sintering (FAST) or Plasma Pressure Compaction (P2C)) involves contemporaneous use of pressure and high-intensity, low-voltage (e.g., 5-12 V), pulsed current to dramatically reduce processing/heating times (e.g., 5-10 minutes (min) instead of several hours) and yield high-density components. In one embodiment, a pulsed DC current is transmitted to the deposited the sintering powder 204a using conductive pads 212 as electrodes, while pressure (e.g., between 10 megapascals (MPa) up to 500 MPa or more) is simultaneously axially applied to the sintering powder 204a via reciprocation of the conductive pads 212 under mono-axial mechanical force. A “mono-axial force” is herein defined to mean a force applied along a single axis or direction creating mono-axial compression. The mold 208 and sintering powder 204a are generally placed under vacuum during at least a portion of the process. Pulsed-current patterns (ON: OFF), typically in milliseconds, enable high heating rates (up to 1000° C./min or more), and rapid cooling/quenching rates of (up to 200° C./min or more) for heating the sintering powder 204a to temperatures ranging from under 1000° C. to 2500° C. In one embodiment, the ON-OFF DC pulse-energizing of the SPS process generates one or more of the following in the Sintering powder: 1) spark plasma, 2) spark impact pressure, 3) Joule heating, and 4) an electrical field diffusion effect.

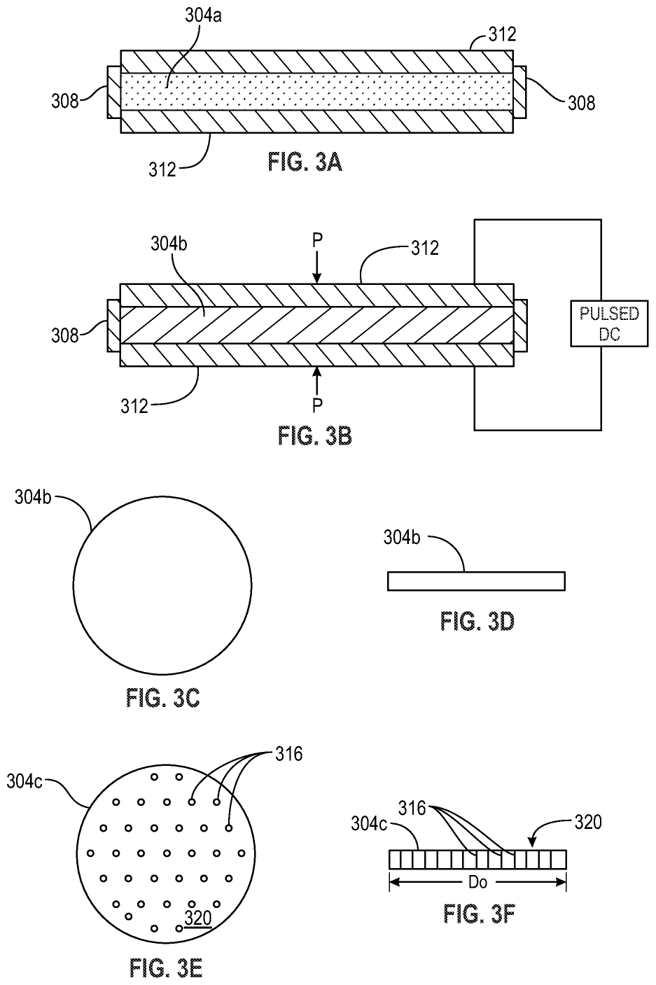

It is appreciated that the scale and geometry of the mold 208, conductive pads 212, sintering powder 204a, and SPS-formed edge ring 204b provided in the schematic views of FIGS. 2A and 2B (as well elements detailed in FIG. 3A and FIG. 3B) are provided for illustrative purposes only, and such elements may vary as to size, scale, shape, and form with respect to each other. Furthermore, it is appreciated that mold 208 and conductive pads 212 may be provided as part of an SPS apparatus (not shown) comprising one or more of the following: vertical single-axis pressurization mechanism, cooled vacuum chamber, atmosphere controls, vacuum exhaust unit, sintering DC pulse generator and a SPS controller, among other elements.

In one embodiment of an SPS process, provided for exemplary purposes only, sintering of the sintering powder is conducted under vacuum (6<P(Pa)<14) while being simultaneously subjected to a pulsed current. The SPS thermal treatment may be implemented as follows: 1) a degassing treatment performed for a period between 3 minutes to 10 minutes, and preferably with the sintering powder 204a subjected to 3 minutes under limited applied load (e.g. between 10 megapascals (MPa) and 20 MPa) and 2 minutes under increasing load up to 40 MPa to 100 MPa, and 2) heating up to between 1850° C. and 1950° C. at 100° C. min⁻¹ under an applied load between 40 MPa to 100 MPa and a soaking time of 5 minutes at maximum temperature then cooling down to room temperature. It is appreciated that one or more of the SPS process parameters, including sintering powder constituent ratios and particulate size, pressures, temperatures, treatment periods, and current pulse sequences, may be varied as appropriate to optimize the SPS process.

Referring to the side view of FIG. 2C, the SPS-formed edge ring 204b is removed from the mold 208 as an SPS-formed component, and in this embodiment a SPS-formed edge ring 204b having a central channel 216. The SPS-formed edge ring 204b forms a ring shaped spark plasma sintered body with a plasma facing surface. The SPS-formed component is characterized by a high degree of densification, reaching nearly 100% (e.g., 99% or greater relative density, and preferably between 99.5% and 100% relative density) with isotropic properties having reduced diffusion between grains and minimized or prevented grain growth. The ring shaped spark plasma sintered body comprises a sintering powder that consists essentially of a doped silicon carbide powder, wherein the dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein the dopant is at least one of B, W, molybdenum (Mo), Al, or Ta, or may be pure B₄C, WC, TaC, W, or Mo.

Following the SPS process, the component may be further processed (step 112, e.g., polishing, machining, or like process) to specifically adapt the component for use in a plasma processing chamber. It is appreciated that the mold and/or SPS process may be structured so that the further processing in step 112 is not required. The SPS-formed edge ring 204b may be formed as a near net shape part (NNS). A NNS part requires subsequent machining removing less than 20% of the volume of the NNS part.

Referring to the side view of FIG. 2D, the Spark Plasma Sintered formed edge ring 204b is further processed to form the processed edge ring 204c. For example, one or more surfaces 220 (e.g., inner surface and diameter Dᵢ of central channel 216, outer circumferential surface having outer diameter Dₒ, and/or top or bottom surfaces) of the SPS-formed edge ring 204b may be polished, honed, machined, etc. to form an edge ring 204c specifically adapted for use in a plasma processing chamber.

The processed SPS body is then mounted or otherwise installed in a cryogenic plasma processing chamber (step 116), wherein the SPS component is used in the cryogenic plasma processing chamber (step 120) for performing cryogenic plasma processing of one or more wafers or substrates. During cryogenic plasma processing, one or more surfaces of the SPS component is exposed to plasma and/or dielectric-etch processes.

The cryogenic plasma processing performed by the cryogenic plasma processing chamber may include one or more processes of etching, depositing, passivating, or another plasma process. The cryogenic plasma processing may also be performed in combination with non-plasma processing and non-cryogenic processes. Such processes may expose the various components of the plasma processing chamber to plasmas containing halogen and/or oxygen that result in erosion or degradation of the part. In an embodiment, the SPS component is exposed to a cryogenic etch process.

The SPS process illustrated in FIG. 1 is particularly useful for fabricating consumable dielectric plasma processing chamber components. More specifically, the processes illustrated in FIG. 1 and FIG. 2A through FIG. 2D are particularly suited for forming and/or conditioning one or more components of a plasma processing chamber to inhibit or minimize consumption of the component via plasma and etching processes inherent in the plasma processing chamber. Such components include pinnacles and electrostatic chucks (ESCs), in addition to high flow liners, gas distribution plates, and edge rings, among other parts in the plasma processing chamber that may be exposed to plasma or energetic ions.

Accordingly, FIG. 3A through FIG. 3F illustrate another embodiment of a method of fabricating a plasma processing component, and in particular a chamber gas distribution plate, using the SPS process in accordance with the present description. FIG. 3A shows a cross-section view of a sintering powder 304a as described in the previous embodiment placed in a recess or cavity of mold 308 for fabricating a gas distribution plate of a plasma processing chamber. The mold 308 is configured for processing the sintering powder 304a according to the SPS process. One embodiment includes a pair of conductive pads 312 that enclose upper and lower ends of the mold 308 cavity and act as pistons or punches to apply a compressive force on the sintering powder 304a within the mold 308.

Referring to the cross-section view of FIG. 3B, the sintering powder 304a is then subjected to SPS to form the sintering powder into a Spark Plasma Sintered formed disk 304b (step 108) via simultaneous application of compressive force P and pulsed current applied at conductive pads 312 according to the SPS process detailed above with respect to FIG. 2B.

Referring to the respective plan and side views of FIG. 3C and FIG. 3D, the SPS-formed disk 304b is removed from the mold 308 and is characterized by a high degree of densification, reaching nearly 100% with isotropic properties having reduced diffusion between grains and minimized or prevented grain growth. In various embodiments, the densification provides a densification of 99% or greater relative density, and preferably between 99.5% and 100% relative density. The formed disk 304b is a disk shaped component body.

Referring to the respective plan and side views of FIG. 3E and FIG. 3F, the SPS-formed disk 304b is further processed to form a processed gas distribution plate 304c. For example, a plurality of gas inlet holes 316 may be drilled into the formed disk 304b to form a gas distribution plate 304c. In the illustration shown in FIG. 3E and FIG. 3F, the holes 316 are not drawn to scale in order to better illustrate the embodiment. In different embodiments, the holes 316 may have various spacing and/or geometric patterns, e.g., circular, grid, etc. Furthermore, one or more surfaces (e.g., outer circumferential surface having diameter Dₒ, and/or top or bottom surfaces) of the SPS-formed disk 304b may be polished, honed, machined, etc. to form a gas distribution plate 304c specifically adapted from use in a plasma processing chamber. The gas distribution plate 304 is adapted to receive gas from a gas source and provide the gas into a plasma processing chamber. In this embodiment, one of the polished surfaces is a plasma facing surface 320. The holes 316 are drilled into the plasma facing surface 320. The plasma facing surface 320 is a surface facing or exposed to a plasma when used in a plasma processing chamber. When the plasma facing surface 320 is exposed to plasma or a remote plasma, the plasma facing surface may also be called a plasma exposed surface.

The plasma processing components (e.g., edge ring 204c, gas distribution plate 304c) generated from the SPS process are resistant to erosion from exposure to plasma, such that the component is either no longer a consumable, or substantially inhibits consumption to limit or obviate the need to change or replace the component due to erosion. Being more etch resistant, components fabricated and installed via the process illustrated in FIG. 1 also minimize/prevent the generation of impurities during plasma processing. The SPS process detailed in FIG. 1 is also particularly amenable for fabricating large parts, e.g., forming edge rings 204c and gas distribution plates 304c having outer diameters (Dₒ) of 14 inches (35.56 centimeters) or greater.

The SPS-formed components provide an advantage of better manufacturability and lower cost over conventional edge ring manufacturing processes where material is built up layer by layer in a CVD process.

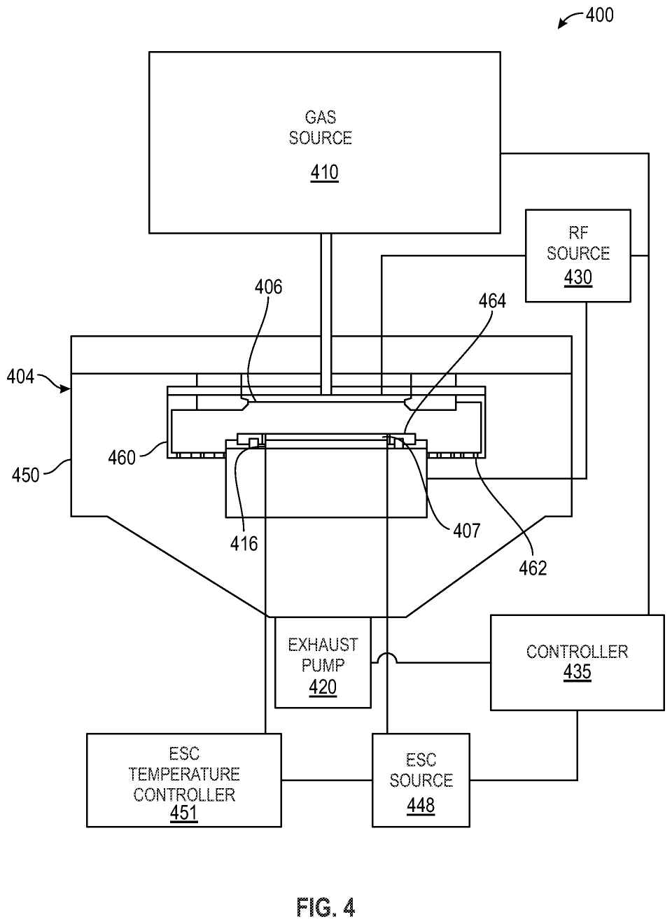

Referring to the schematic system view of FIG. 4, one or more processed and SPS-formed components may be mounted or otherwise installed for use in a cryogenic plasma processing system 400 for processing a wafer or substrate 407. The plasma processing chamber in this embodiment is a CCP (capacitively coupled plasma) reactor. In other her embodiments, the plasma processing chamber may be inductively coupled or use other RF power systems.

In one exemplary configuration, the one or more processed and SPS-formed components comprise consumable plasma processing chamber components such as an edge ring, gas distribution plate, high flow liner, etc. In some embodiments, the cryogenic plasma processing system 400 comprises a gas distribution plate 406, also referred to as a “showerhead” for providing a gas inlet within a plasma processing chamber 404. The gas distribution plate 406 may be mounted in a plasma processing chamber 404 along with an electrostatic chuck (ESC) 416, all being enclosed by a chamber wall 450. Within the plasma processing chamber 404, a substrate or wafer 407 is positioned on top of the ESC 416 that acts as a wafer support to support the substrate 407. The ESC 416 may provide a bias from an ESC power source 448. A gas source 410 is connected to the plasma processing chamber 404 through the gas distribution plate 406. An ESC temperature controller 451 is connected to the ESC 416 and provides temperature control of the ESC 416. In this embodiment, the ESC temperature controller may be part of a cooling system that is able to cool the ESC 416 to cryogenic temperatures of less than-20° C. or −60° C. A radio frequency (RF) power source 430 provides RF power to the ESC 416 and an upper electrode. In this embodiment, the upper electrode is the gas distribution plate 406. In a preferred embodiment, 13.56 megahertz (MHz), 2 MHz, 60 MHz, and/or optionally, 27 MHz power sources make up the RF power source 430 and the ESC power source 448. A controller 435 is controllably connected to the RF power source 430, the ESC power source 448, an exhaust pump 420, and the gas source 410.

A high flow liner 460 is a liner within the plasma processing chamber 404, and may also be formed, installed, and used in accordance with the steps illustrated in FIG. 1. The high flow liner 460 confines gas from the gas source and has slots 462. The slots 462 maintain a controlled flow of gas to pass from the gas source 410 to the exhaust pump 420.

An edge ring 464 surrounds the substrate 407. The plasma processing chamber 404 uses the edge ring 464 to plasma process the substrate 407. It is desirable that the top surface of the edge ring 464 be level with a top surface of the substrate 407. Therefore, the use of an SPS-formed edge ring 204c as edge ring 464 obviates various mechanisms that are typically provided to move the edge ring as the edge ring is consumed in order to keep the top surface of the edge ring even with the top surface of the substrate. In addition, once an edge ring is sufficiently consumed, the edge ring must be replaced, causing downtime for the plasma processing chamber. In other embodiments, such components may be placed in locations shielded from plasma. Ceramic edge rings have a low coefficient of thermal expansion and good electrical and thermal conductivity. In addition, the component is a dielectric component with an etch resistivity of greater than 25 ohms centimeter (ohms-cm).

In other embodiments, the components may be parts of other types of plasma processing chambers such as a TCP (transformer coupled plasma) reactor, a bevel plasma processing chambers or like device. Examples of components of plasma processing chambers that may be provided in various embodiments are confinement rings, plasma exclusion rings, edge rings, the electrostatic chuck, ground rings, chamber liners, door liners, the pinnacle, a showerhead, a dielectric power window, gas injectors, edge rings, ceramic transfer arms, or other components. In some embodiments, the cryogenic temperature is a temperature of less than −60° C. In some embodiments, a cryogenic etch may be used to etch stacks of alternating layers of silicon oxide and polysilicon (OPOP) or stacks of alternating layers of silicon oxide and silicon nitride (ONON). The component may be made of sintered powders of materials that are used as hardmasks in such processes, since some hardmasks are of a plasma resistant dielectric material that provides a volatile etch product.

In various embodiments, the sintering powder consists essentially of SiC doped with Al. SiC and Al are not exotic materials. High purity SiC and Al may be obtained at a low expense. In addition, Al dopant may be evenly dispersed in the SiC grain. In various embodiments, when the component body is eroded, the sintering powder forms volatile etch products.

In various embodiments, the sintering powder consists essentially of B₄C. Sintering powder that consists essentially of B₄C is able to be easily densely sintered.

In various embodiments, the sintering powder consists essentially of W or Mo. In other embodiments, the sintering powder consists essentially of WC doped with at least one of B, W, Mo, Al, Ta, and B₄C.

In various embodiments, the sintering powder consists essentially of SiC doped with Y. SiC and Y are not exotic materials. High purity SiC and Y may be obtained at a low expense. In embodiments where the component is made of sintered pure WC, a high density component would be easy to form by sintering.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. An apparatus for plasma processing a wafer at cryogenic temperatures, comprising:
a plasma processing chamber;
a wafer support for supporting a wafer within the plasma processing chamber;
a gas source for providing gas to the plasma processing chamber;
a cooling system for cooling the wafer support; and
a component, comprising a spark plasma sintered body comprising a sintering powder comprising at least one of a doped silicon carbide powder, wherein a dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein a dopant is at least one of B, W, molybdenum (Mo), Al, and Ta, or pure B₄C, WC, TaC, W, or Mo.

2. The apparatus, as recited in claim 1, wherein an atomic fraction of the dopant to sintering powder is in a range of 0.10% to 10%.

3. The apparatus, as recited in claim 1, wherein the component is at least one of a gas distribution plate, edge ring, or liner of the plasma processing chamber.

4. The apparatus, as recited in claim 1, wherein the sintering powder consists essentially of at least one of a doped silicon carbide powder, wherein the dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein the dopant is at least one of B, W, molybdenum (Mo), Al, and Ta, or pure B₄C, WC, TaC, W, or Mo.

5. The apparatus, as recited in claim 1, wherein an atomic fraction of the dopant to sintering powder is in a range of 0.10% to 1%.

6. The apparatus, as recited in claim 1, wherein an atomic fraction of the dopant to sintering powder is in a range of 1% to 5%.

7. The apparatus, as recited in claim 1, wherein an atomic fraction of the dopant to sintering powder is in a range of 1% to 10%.

8. The apparatus, as recited in claim 1, wherein the cooling system is able to cool the wafer support to a temperature of less than −20° C.

9. A component for use in a cryogenic plasma processing system, comprising a spark plasma sintered body comprising a sintering powder comprising at least one of a doped silicon carbide powder, wherein a dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein a dopant is at least one of B, W, molybdenum (Mo), Al, and Ta, or pure B₄C, WC, TaC, W, or Mo.

10. A method for making a component for use in a plasma processing chamber, comprising:
placing a sintering powder in a mold, wherein the sintering powder comprises at least one of a doped silicon carbide powder, wherein a dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein a dopant is at least one of B, W, molybdenum (Mo), Al, and Ta, or pure B₄C, WC, TaC, W, or Mo;
subjecting the sintering powder to spark plasma sintering (SPS) to form a spark plasma sintered component; and
machining the spark plasma sintered component into a plasma processing chamber component.

11. The method, as recited in claim 10, wherein an atomic fraction of the dopant to sintering powder is in a range of 0.10% to 10%.

12. The method, as recited in claim 10, wherein the component is at least one of a gas distribution plate, edge ring, or liner of the plasma processing chamber.

13. The method, as recited in claim 10, wherein the sintering powder consists essentially of at least one of a doped silicon carbide powder, wherein the dopant is at least one of aluminum (Al), yttrium (Y), tungsten (W), tantalum (Ta), tungsten carbide (WC), tantalum carbide (TaC), and aluminum-silicon carbide (AlSiC), or a doped carbide, wherein the carbide is at least one of boron carbide (B₄C), WC, or TaC and wherein the dopant is at least one of B, W, molybdenum (Mo), Al, and Ta, or pure B₄C, WC, TaC, W, or Mo.

14. The method, as recited in claim 10, wherein an atomic fraction of the dopant to sintering powder is in a range of 0.10% to 1%.

15. The method, as recited in claim 10, wherein an atomic fraction of the dopant to sintering powder is in a range of 1% to 5%.

16. The method, as recited in claim 10, wherein an atomic fraction of the dopant to sintering powder is in a range of 1% to 10%.

17. The method, as recited in claim 10, further comprising mounting the component is a plasma processing chamber.

18. The method, as recited in claim 17, further comprising processing a wafer in the plasma processing chamber, while the component is mounted in the plasma processing chamber.

19. The method, as recited in claim 18, wherein the processing the wafer is a cryogenic etch process.

20. A component for use in a plasma processing chamber, the component made by the method of claim 10.
